(19) United States
(12) Patent Application Publication
(10) Pub. No.: US 2019/0198298 A1
(43) Pub. Date: Jun. 27, 2019

(54) PLASMA ETCHING APPARATUS AND PLASMA ETCHING METHOD

(71) Applicant: Tokyo Electron Limited, Tokyo (JP)

(72) Inventors: Jun HIROSE, Miyagi (JP); Takehiro UEDA, Miyagi (JP)

(21) Appl. No.: 16/225,326

(22) Filed: Dec. 19, 2018

(30) Foreign Application Priority Data
Dec. 21, 2017 (JP) 2017-245362

(51) Int. Cl. H01J 37/32; H01L 21/3065; H01L 21/67; H01L 21/683

(52) U.S. Cl. CPC H01J 37/32642; H01J 37/32449; H01J 37/32697; H01L 21/6831; H01J 37/32532; H01L 21/3065; H01L 21/67248; H01J 37/32522

(57) ABSTRACT

There is provision of a plasma etching apparatus including a processing vessel capable of being evacuated, a lower electrode provided in the processing vessel that is configured to place a substrate, an upper electrode provided in the processing vessel arranged in parallel with the lower electrode so as to face each other, a process gas supply unit configured to supply process gas to a processing space between the upper electrode and the lower electrode, a high frequency power supply unit configured to supply high frequency electric power for generating plasma from process gas, a focus ring surrounding a periphery of the substrate, a direct current (DC) power source configured to output DC voltage applied to the focus ring, a heating unit configured to heat the focus ring, and a temperature measurement unit for measuring temperature of the focus ring.

### CROSS-REFERENCE TO RELATED APPLICATIONS

This patent application is based on and claims priority to Japanese Patent Application No. 2017-245362 filed on Dec. 21, 2017, the entire contents of which are incorporated herein by reference.

### BACKGROUND OF THE INVENTION

### 1. Field of the Invention

The present invention generally relates to a plasma etching apparatus and a plasma etching method.

### 2. Description of the Related Art

In a processing chamber of a plasma etching apparatus, a focus ring is disposed on a stage so as to surround a periphery of a wafer, in order to direct plasma toward a surface of the wafer. During plasma processing, as the focus ring is exposed to plasma, the focus ring becomes worn.

As a result, because a level difference is generated on a sheath at an edge of the wafer and an incident angle of ions is tilted, tilting occurs on an etching profile. Also, as an etching rate at the edge of the wafer varies, an etching rate in a wafer becomes uneven. Accordingly, when a focus ring is worn to a certain amount, the focus ring is replaced with a new one. However, a time for replacing a focus ring is one of factors for degrading productivity.

Some technologies have been developed in order to alleviate the problem. For example, Patent Document 1 discloses a technique for controlling distribution of an etching rate of a surface by applying DC (direct current) voltage to a focus ring from a DC power source. Patent Document 2 discloses a technique for measuring degree of abrasion of a focus ring based on a change of temperature of the focus ring according to passage of time. Patent Document 3 discloses a technique for controlling DC voltage to be applied to a focus ring, in accordance with a measured result of a thickness of the focus ring.

However, appropriate DC voltage to be applied to a focus ring varies depending on degree of abrasion of the focus ring and a process condition. Thus, it is difficult for the techniques disclosed in Patent Document 1 or Patent Document 2 to appropriately control DC voltage to be applied to a focus ring in accordance with degree of abrasion of the focus ring and the like.

Although, in the technique disclosed in Patent Document 3, DC voltage applied to a focus ring is controlled in accordance with a thickness of the focus ring, because abrasion of a focus ring occurs in not only a thickness direction but also a width direction, it is difficult for the techniques disclosed in Patent Document 3 to appropriately control DC voltage to be applied to a focus ring in accordance with degree of abrasion of the focus ring and the like. Also, as it is difficult to directly measure a thickness of a focus ring installed inside a plasma etching apparatus, enabling the techniques disclosed in Patent Document 3 requires high cost.

### CITATION LIST

### Patent Document

[Patent Document 1] Japanese Patent No. 5281309
[Patent Document 2] Japanese Patent No. 6027492
[Patent Document 3] Japanese Laid-open Patent Application Publication No. 2005-203489

### SUMMARY OF THE INVENTION

According to an aspect of the present invention, a plasma etching apparatus is provided to solve the above problem. The plasma etching apparatus includes a processing vessel capable of being evacuated; a lower electrode provided in the processing vessel that is configured to place a substrate; an upper electrode provided in the processing vessel that is arranged in parallel with the lower electrode so as to face each other; a process gas supply unit configured to supply process gas to a processing space between the upper electrode and the lower electrode; a high frequency power supply unit configured to supply high frequency electric power for generating plasma from process gas; a focus ring surrounding a periphery of the substrate; a direct current (DC) power source configured to output DC voltage applied to the focus ring; a heating unit configured to heat the focus ring; and a temperature measurement unit configured to measure temperature of the focus ring.

According to another aspect of the present invention, a plasma etching method including an etching step of etching a substrate by using the above described plasma etching apparatus is provided. In the etching step, the DC voltage applied to the focus ring is controlled based on temperature of the focus ring measured by the temperature measurement unit, by accessing a memory unit storing information indicating a relationship between temperature rising rate of the focus ring and DC voltage.

### BRIEF DESCRIPTION OF THE DRAWINGS

FIG. 1 is a diagram illustrating an example of a plasma etching apparatus according to an embodiment;

FIG. 2A and FIG. 2B are diagrams illustrating a variation of an etching rate and occurrence of tilting that are caused by abrasion of a focus ring;

FIG. 3 is a diagram illustrating an example of a cross section of a peripheral structure of the focus ring according to the embodiment;

FIG. 4 is a flowchart of an example of a process for calculating a relationship between temperature rising rate and DC voltage according to the embodiment;

FIG. 5 illustrates an example of a graph representing the relationship between temperature rising rate and DC voltage according to the embodiment;

FIG. 6 is a flowchart illustrating an example of a DC voltage control process according to the embodiment;

FIG. 7 is a diagram illustrating an example of a cross section of a peripheral structure of a focus ring according to modified example; and

FIG. 8 is a diagram illustrating an example of a system for controlling DC voltage according to the embodiment.

### DETAILED DESCRIPTION OF EMBODIMENTS

In the following, embodiments of the present invention will be described with reference to the drawings. Note that in the following descriptions and the drawings, elements having substantially identical features are given the same reference symbols and overlapping descriptions may be omitted.

[Plasma Etching Apparatus]

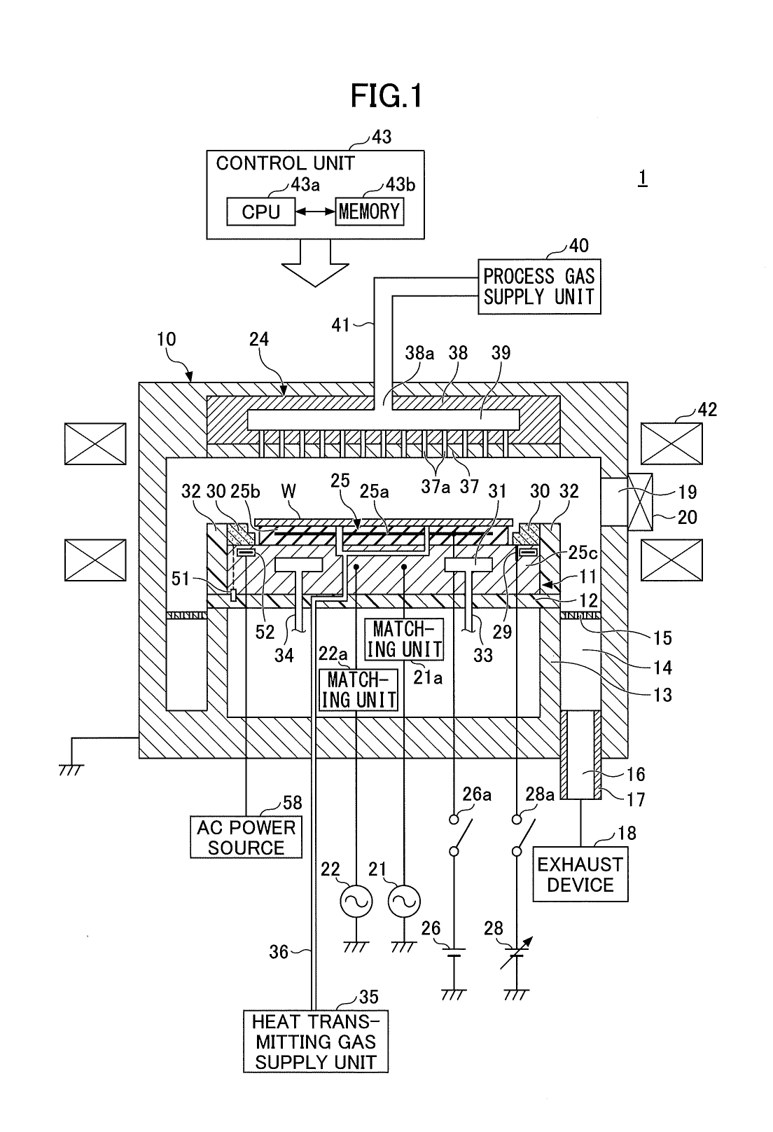

First, an example of a plasma etching apparatus 1 according to an embodiment will be described with reference to FIG. 1. FIG. 1 is a diagram illustrating a cross section of the plasma etching apparatus 1 according to the embodiment. The plasma etching apparatus 1 according to the present embodiment is a plasma etching apparatus of a reactive ion etching (RIE) type.

The plasma etching apparatus 1 includes a cylindrical processing vessel 10 capable of being evacuated. The processing vessel 10 is formed of metal, such as aluminum or stainless steel. The inside of the processing vessel 10 is a processing chamber for performing a plasma process such as plasma etching or plasma CVD. The processing vessel 10 is grounded.

A disc shaped stage 11 is provided in the processing vessel 10. An example of a workpiece to be placed on the stage 11 includes a semiconductor wafer W (hereinafter referred to as a “wafer W”). The stage 11 is supported by a cylindrical supporting member 13 that extends upward from the bottom of the processing vessel 10, via a cylindrical holding member 12 formed of aluminum oxide (Al₂O₃).

The stage 11 includes an electrostatic chuck 25. The electrostatic chuck 25 includes a base 25c formed of aluminum, and a dielectric layer 25b disposed on the base 25c. On an outer circumference side of an upper surface of the base 25c, a focus ring 30 is disposed so as to surround a periphery of a wafer W. An outer circumference of the base 25c and an outer circumference of the focus ring 30 are covered by an insulator ring 32.

An attracting electrode 25a made from conductive film is embedded in the dielectric layer 25b. A direct current (DC) power source 26 is connected to the attracting electrode 25a via a switch 26a. The electrostatic chuck 25 generates electrostatic force (Coulomb force) by DC voltage applied from the DC power source 26 to the attracting electrode 25a, and a wafer W is attracted to and held by the electrostatic chuck 25 by the generated electrostatic force.

The focus ring 30 is made from silicon. In the base 25c, a heater 52 is embedded at a position close to a bottom surface of the focus ring 30. An alternate current (AC) power source 58 is connected to the heater 52. When electric power is supplied from the AC power source 58 to the heater 52, the heater 52 is heated and the focus ring 30 is also heated. Temperature of the bottom surface of the focus ring 30 can be measured by a radiation thermometer 51.

A variable DC power source 28 is connected to an electrode 29 via a switch 28a. Because the electrode 29 is in contact with the focus ring 30, DC voltage output from the variable DC power source 28 is applied to the focus ring 30.

Further, as will be described below, in the present embodiment, by appropriately controlling magnitude of DC voltage applied from the variable DC power source 28 to the focus ring 30 in accordance with degree of abrasion of the focus ring, a thickness of sheath generated above an upper surface of the focus ring 30 is controlled. Accordingly, occurrence of tilting is suppressed, and distribution of an etching rate of a surface can be controlled. The variable DC power source 28 is an example of a DC power source for outputting DC voltage to be applied to the focus ring 30.

A first high frequency power source 21 is connected to the stage 11 via a matching unit 21a. The first high frequency power source 21 supplies, to the stage 11, high frequency electric power of a first frequency (such as a frequency of 13 MHz) for generating plasma or for RIE (hereinafter, the high frequency electric power of the first frequency may also be referred to as “first high frequency electric power”). Also, a second high frequency power source 22 is connected to the stage 11 via a matching unit 22a. The second high frequency power source 22 supplies high frequency electric power of a second frequency lower than the first frequency (such as a frequency of 3 MHz) for generating bias voltage (hereinafter, the high frequency electric power of the second frequency may also be referred to as “second high frequency electric power”). That is, the stage 11 functions as a lower electrode.

In the base 25c, a coolant chamber 31 of an annular shape, which extends in a circumferential direction, is provided. From a chiller unit, coolant at a predetermined temperature, such as cooling water, is supplied to the coolant chamber 31, and the coolant circulates in the coolant chamber 31 via pipes 33 and 34, in order to cool the electrostatic chuck 25.

To the electrostatic chuck 25, a heat transmitting gas supply unit 35 is connected via a gas supply line 36. The heat transmitting gas supply unit 35 supplies heat transmitting gas to a space between the upper surface of the electrostatic chuck 25 and a bottom surface of a wafer W. Gas having good heat conductivity, such as He gas, may preferably be used as a heat transmitting gas.

Between a side wall of the processing vessel 10 and the cylindrical supporting member 13, an exhaust path 14 is formed. At an entrance of the exhaust path 14, an annular baffle plate 15 is provided. At a bottom of the exhaust path 14, an exhaust port 16 is provided. An exhaust device 18 is connected to the exhaust port 16 via an exhaust pipe 17. The exhaust device 18 includes a vacuum pump, and can reduce pressure of a processing space in the processing vessel 10 to a desirable quality of vacuum. Also, the exhaust pipe 17 includes an automatic pressure control valve (hereinafter referred to as an “APC”) of a variable butterfly valve. The APC automatically controls pressure in the processing vessel 10. Further, a gate valve 20 is provided at the side wall of the processing vessel 10, which is used for opening and/or closing a loading/unloading port 19 for a wafer W.

A gas shower head 24 is mounted to a ceiling of the processing vessel 10. The gas shower head 24 includes an electrode plate 37, and an electrode supporting member 38 that detachably supports the electrode plate 37. The electrode plate 37 includes a large number of gas holes 37a. The gas shower head 24 is arranged in parallel with the stage 11 such that the gas shower head 24 faces the stage 11 which also acts as the lower electrode. The gas shower head 24 also acts as an upper electrode.

A buffer chamber 39 is provided in the electrode supporting member 38. The buffer chamber 39 includes a gas inlet port 38a, and a process gas supply unit 40 is connected to the gas inlet port 38a via a gas supplying pipe 41. The process gas supply unit 40 supplies process gas to the processing space between the gas shower head 24 and the stage 11, through the gas holes 37a. Further, at a periphery of the processing vessel 10, annular magnets 42 are provided coaxially.

Each component of the plasma etching apparatus 1 is connected to a control unit 43. The control unit 43 controls each of the components of the plasma etching apparatus 1. Examples of the component include the exhaust device 18, the matching units 21a and 22a, the first high frequency power source 21, the second high frequency power source 22, the switches 26a and 28a, the DC power source 26, the variable DC power source 28, the heat transmitting gas supply unit 35, and the process gas supply unit 40.

The control unit 43 is a computer having a CPU 43a and a memory 43b. The CPU 43a reads out a control program for the plasma etching apparatus 1 and a process recipe that are stored in the memory 43b, to control an etching process performed in the plasma etching apparatus 1.

The control unit 43 also maintains, in the memory 43b, a table storing information indicating a relationship between temperature rising rate of the focus ring 30 and DC voltage that is calculated in a pre-process of a DC voltage control process of the focus ring 30 to be described below. The memory 43b is an example of a memory unit storing a relationship between temperature rising rate and DC voltage.

For example, when an etching process is performed in the plasma etching apparatus 1, the gate valve 20 is opened first. Next, a wafer W is loaded into the processing vessel 10 and placed on the electrostatic chuck 25. Subsequently, DC voltage from the DC power source 26 is applied to the attracting electrode 25a to attract the wafer W to the electrostatic chuck 25.

Also, heat transmitting gas is supplied to a space between the upper surface of the electrostatic chuck 25 and a bottom surface of the wafer W. Next, process gas from the process gas supply unit 40 is supplied to the inside of the processing vessel 10, and pressure in the processing vessel 10 is reduced by the exhaust device 18 and the like. Further, first high frequency electric power and second high frequency electric power are supplied to the stage from the first high frequency power source 21 and the second high frequency power source 22 respectively.

In the processing vessel 10 of the plasma etching apparatus 1, a magnetic field of a horizontal direction is created by the magnets 42, and an RF electric field of a vertical direction is generated by high frequency electric power applied to the stage 11. Because of the generated magnetic field and the generated electric field, the process gas introduced from the gas shower head 24 is changed to plasma, and a given etching process is applied to the wafer W by radicals or ions in the plasma.

The first high frequency power source 21 is an example of a high frequency power supply unit that supplies, to the stage 11, high frequency electric power for generating plasma from process gas. However, the high frequency power supply unit may supply high frequency electric power for generating process gas plasma to the gas shower head 24, instead of the stage 11.

The heater 52 is an example of a heating unit that heats the focus ring 30. The heating unit is not limited to the heater 52, and another heating medium may be used. The radiation thermometer 51 is an example of a temperature measurement unit for measuring temperature of the focus ring 30. However, the temperature measurement unit is not limited to a specific type of thermometer. For example, a fiber optical thermometer such as Luxtron or a thermocouple may be used as the temperature measurement unit.

[Abrasion of Focus Ring]

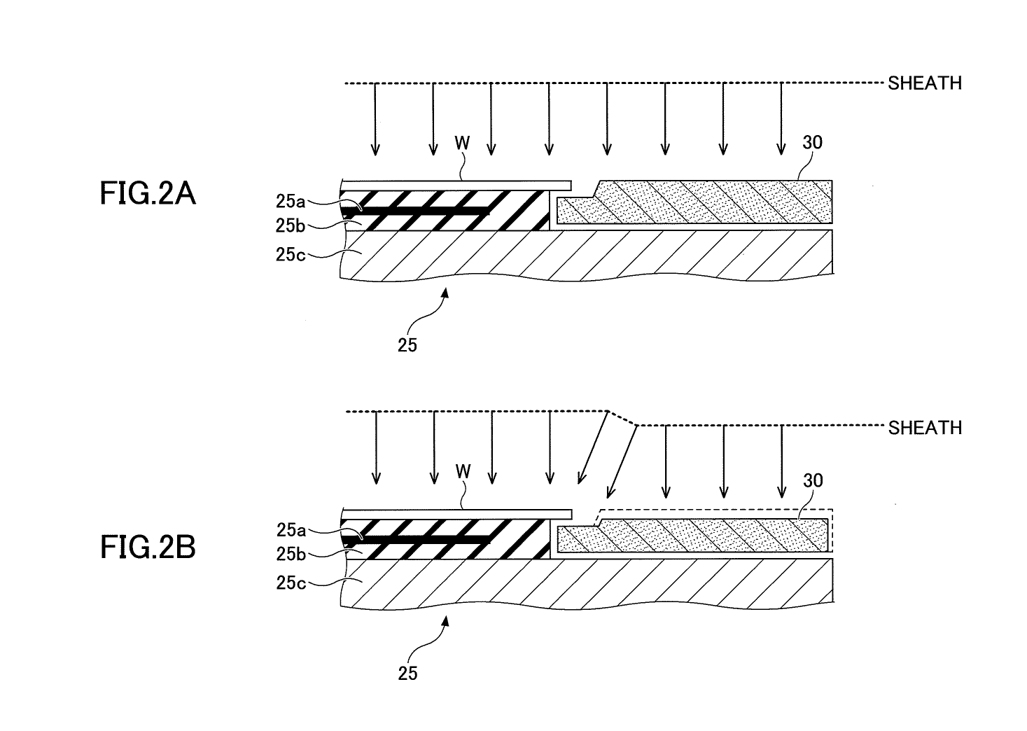

Next, a change of sheath, a variation of an etching rate, and occurrence of tilting, which are caused by abrasion of the focus ring, will be described with reference to FIGS. 2A and 2B. As illustrated in FIG. 2A, when the focus ring 30 is new, a thickness of the focus ring 30 is designed such that an upper surface of a wafer is positioned at the same height as the height of the upper surface of the focus ring 30. In such a state, during plasma processing, the sheath above the wafer W and the sheath above the focus ring 30 are at the same height, and an incident angle of ions from plasma above the wafer W and the focus ring 30 is vertical. As a result, an etching profile of a hole or the like formed on the wafer W becomes vertical. That is, tilting, in which an etching profile tilts, does not occur. Also, an etching rate becomes uniform on an entire surface of the wafer W.

However, by plasma processing being performed, as the focus ring 30 is exposed to plasma, the focus ring 30 abrades. Thus, as illustrated in FIG. 2B, because the focus ring 30 becomes thinner, the height of the upper surface of the focus ring 30 becomes lower than the height of the upper surface of the wafer W, and the sheath above the focus ring 30 becomes lower than the sheath above the wafer W in height.

At an edge of the wafer W in which a height difference of sheath occurs, an incident angle of ions becomes slanted (departs from a vertical angle), and tilting may occur in an etching profile. In addition, an etching rate at the edge of the wafer W varies, and the etching rate may become uneven on the surface of the wafer W.

On the other hand, in the present embodiment, by applying DC voltage output from the variable DC power source 28 to the focus ring 30, distribution of an etching rate on a surface and tilting can be controlled.

However, as the focus ring 30 is exposed to plasma during plasma processing, the focus ring 30 abrades gradually. Thus, appropriate magnitude of DC voltage to be applied from the variable DC power source 28 varies in accordance with degree of abrasion of the focus ring 30. Also, as illustrated in FIG. 2B, the abrasion of the focus ring 30 includes not only a decrease in the focus ring 30 in a thickness direction, but also a decrease in a width direction and deterioration of quality of material. Accordingly, in a case in which degree of abrasion of the focus ring 30 is estimated by measuring a thickness of the focus ring 30 and in which DC voltage to be applied from the variable DC power source 28 is calculated based on the estimated degree of abrasion, because the estimated degree of abrasion deviates from an actual degree of abrasion, it is difficult to calculate appropriate DC voltage.

To solve the above problem, in the present embodiment, degree of abrasion of the focus ring 30 is estimated based on heat capacity, and DC voltage to be applied to the focus ring 30 is controlled based on the estimated heat capacity. In the present embodiment, as a physical quantity corresponding to heat capacity, temperature rising rate of the focus ring 30 is measured while the focus ring 30 is heated by the heater 52 to which a constant electric power is supplied. Based on the measured temperature rising rate, degree of abrasion of the focus ring 30 is estimated, and magnitude of DC voltage to be applied is controlled. The above mentioned heat capacity estimated is heat capacity of not only the focus ring 30 but also of peripheral members of the focus ring 30. That is, the above mentioned temperature rising rate of the focus ring 30 corresponds to the heat capacity of the focus ring 30 and the peripheral members of the focus ring 30.

[Focus Ring Peripheral Structure]

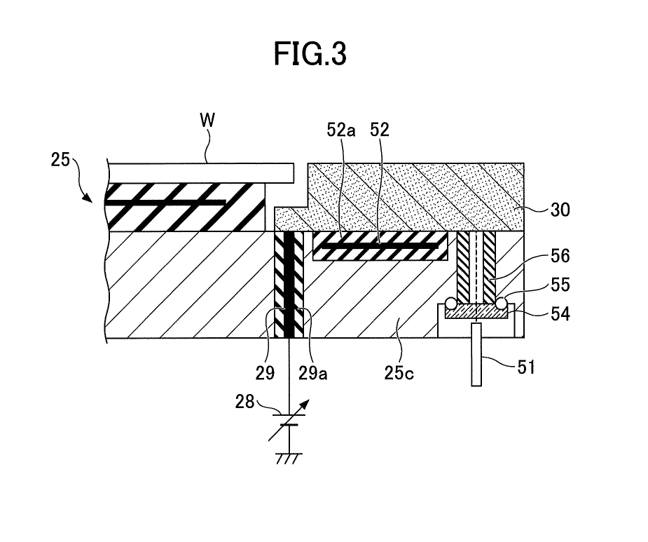

In order to estimate degree of abrasion of the focus ring 30 based on temperature rising rate of the focus ring 30 and to appropriately control magnitude of DC voltage applied to the focus ring 30, information about a relationship between the temperature rising rate and the appropriate DC voltage is obtained first. In the following, a peripheral structure of the focus ring 30 concerning temperature measurement of the focus ring 30, which is used for obtaining information indicating a relationship between temperature rising rate and appropriate DC voltage, will be described with reference to FIG. 3. FIG. 3 is a diagram illustrating an example of a cross section of the peripheral structure of the focus ring according to the present embodiment.

The focus ring 30 is a ring-shaped member, and is disposed on an outer circumference side of the upper surface of the base 25c of the electrostatic chuck 25. In the base 25c, a heater 52 coated with an insulator 52a is provided at a position close to the bottom surface of the focus ring 30. When electric power is supplied from the AC power source 58 to the heater 52, the heater 52 is heated and the focus ring 30 is also heated. The radiation thermometer 51 measures temperature of the bottom surface of the focus ring 30. A tip of the radiation thermometer 51 is disposed in a vicinity of an antireflection-treated glass piece 54 made from material such as Ge. From a tip of the radiation thermometer 51, infrared light or visible light is emitted. The emitted infrared light or visible light passes through a space formed in an insulator 56, reaches the bottom surface of the focus ring 30, and reflects. In the present embodiment, in order to measure temperature of the focus ring 30, intensity of the reflected infrared light or visible light is measured. An O-ring 55 seals the insulator 56 so as to separate a space in the insulator 56 at an atmospheric pressure from a vacuum space in the processing vessel 10. The variable DC power source 28 is connected to the electrode 29 coated with an insulator 29a. From the variable DC power source 28, DC voltage of a magnitude in accordance with degree of abrasion of the focus ring 30 is applied to the electrode 29. When DC voltage is to be applied to the focus ring 30, the control unit 43 determines an optimal DC voltage value to be applied to the focus ring 30, based on the temperature of the focus ring 30 measured by the radiation thermometer 51 and based on the information about the relationship between temperature rising rate of the focus ring 30 and appropriate DC voltage, in order to control the variable DC power source 28 to output the appropriate DC voltage.

[Pre-Process of DC Voltage Control Process]

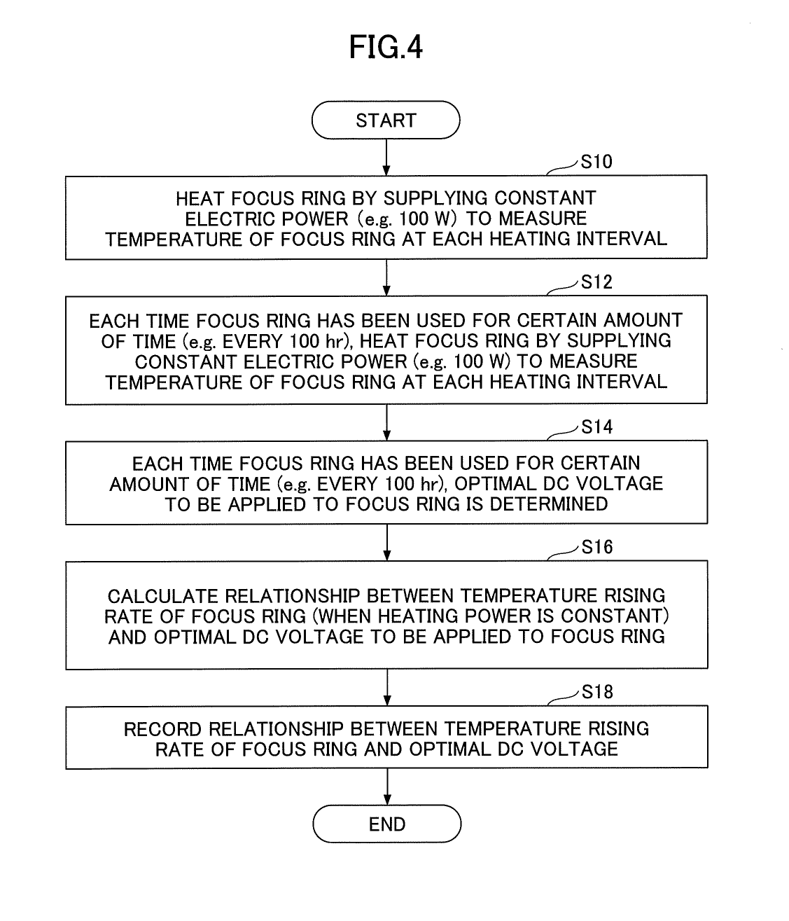

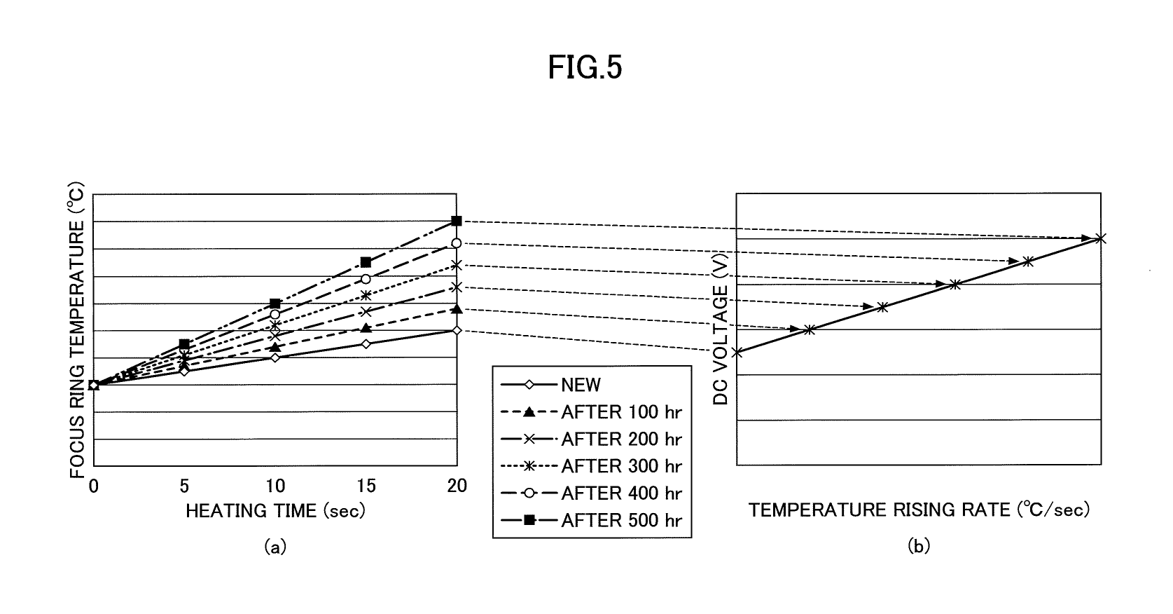

Next, a process for obtaining the information indicating a relationship between temperature rising rate of the focus ring 30 and DC voltage will be described with reference to FIG. 4 and FIG. 5. FIG. 4 is a flowchart of an example of a process for calculating a relationship between temperature rising rate and DC voltage according to the present embodiment (hereinafter, this process may simply be referred to as a “calculation process”). An example of a graph representing a relationship between temperature rising rate and DC voltage according to the present embodiment is illustrated in FIG. 5. The calculation process is performed as a pre-process of the DC voltage control process in which an optimal DC voltage is applied to the focus ring 30.

When starting the calculation process in FIG. 4, a new focus ring 30 is used. The control unit 43 first heats the focus ring 30 by supplying constant electric power (such as 100 W) from the AC power source 58 to the heater 52, and measures temperature of the bottom surface of the focus ring 30 at every heating interval (heating time) (step S10).

Next, each time the focus ring 30 has been used for a predetermined period (for example, each time the focus ring 30 has been used for 100 hours), the control unit 43 heats the focus ring 30 by supplying constant electric power (such as 100 W) from the AC power source 58 to the heater 52, and measures temperature of the bottom surface of the focus ring 30 at every heating interval (heating time) (step S12).

An example of a graph representing an execution result of step S10 and step S12 is illustrated in FIG. 5 (a graph (a) of FIG. 5). In the graph (a) of FIG. 5, a horizontal axis represents a heating time, and a vertical axis represents temperature of the focus ring 30 when the focus ring 30 has been heated for a period corresponding to the heating time. The graph (a) of FIG. 5 represents relationships between heating time and temperature of the focus ring 30, in cases in which the focus ring 30 is new, the focus ring 30 has been used for 100 hours, the focus ring 30 has been used for 200 hours, the focus ring 30 has been used for 300 hours, the focus ring 30 has been used for 400 hours, and the focus ring 30 has been used for 500 hours. From this example (the graph (a)), it is found that an amount of increase in temperature of the focus ring 30 per a certain amount of heating time becomes higher as a usage time of the focus ring 30 increases and degree of abrasion of the focus ring 30 increases, because the focus ring 30 has been exposed to plasma.

Referring back to FIG. 4, each time the focus ring 30 has been used for a predetermined period (for example, each time the focus ring 30 has been used for 100 hours); determination of an optimal magnitude of DC voltage to be applied to the focus ring 30 at this time is performed (by performing experiment using the focus ring 30, or by using other conventional methods) (step S14).

Next, the control unit 43 calculates temperature rising rate of the focus ring 30 (when power supplied to the heater 52 is constant) for each usage time of the focus ring 30, and determines a relationship between temperature rising rate of the focus ring 30 (when power supplied to the heater 52 is constant) and an optimal magnitude of DC voltage to be applied to the focus ring 30 (step S16). Next, the control unit 43 records the calculated relationship into the table in the memory 43b (step S18), and the process terminates.

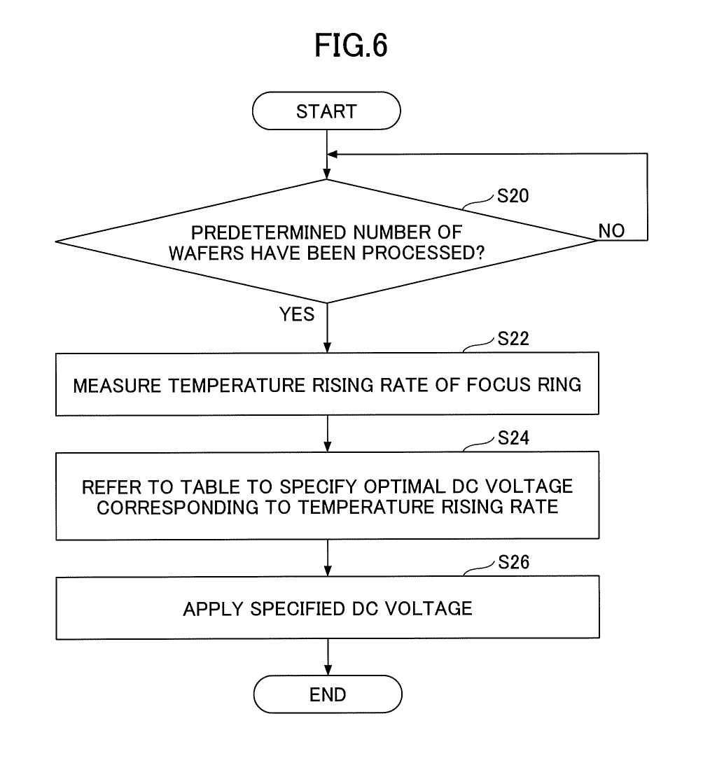

An example of a graph representing a relationship between temperature rising rate and DC voltage, which is obtained by performing the above mentioned calculation process, is illustrated in a graph (b) of in FIG. 5. The usage time of the focus ring 30 corresponds to degree of abrasion of the focus ring 30. As the focus ring 30 abrades, heat capacity of the focus ring 30 becomes smaller and temperature rising rate increases. Thus, by calculating an optimal magnitude of DC voltage corresponding to temperature rising rate, as illustrated in the graph (b) of FIG. 5, an optimal magnitude of DC voltage corresponding to degree of abrasion of the focus ring 30 is estimated. Based on information of the calculated relationship between temperature rising rate and DC voltage, control for applying, to the focus ring 30, an optimal DC voltage corresponding to degree of abrasion of the focus ring 30, is realized. In the following, the DC voltage control process according to the present embodiment, in which an optimal DC voltage corresponding to degree of abrasion of the focus ring 30 is applied to the focus ring 30, will be described with reference to FIG. 6. FIG. 6 is a flowchart illustrating an example of the DC voltage control process according to the present embodiment.

[DC Voltage Control Process]

In the DC voltage control process, temperature of the focus ring 30 is measured while raising temperature of the heater 52 disposed under the focus ring 30, by supplying constant electric power (such as 100 W) from the AC power source 58 to the heater 52, in order to calculate temperature rising rate of the focus ring 30. The DC voltage control process is started when a certain period of time has passed since the heating of the focus ring 30, by supplying constant electric power to the heater 52, was started. Note that the DC voltage control process may preferably be started except for a period while a process of etching a wafer W is being performed. However, the DC voltage control process may be performed at any time after the above mentioned calculation process has been performed.

When starting the DC voltage control process, the control unit 43 determines whether a predetermined number of wafers W have been processed or not (step S20). The predetermined number wafers W may be a single wafer W, or may be one lot of (for example, 25 pieces of) wafers W. Further, although the present embodiment describes a case in which the number of processed wafers W is used for determination, other determination methods may be used. For example, the control unit 43 may determine whether or not an etching process has been performed for a given period of time, and if the given period of time has elapsed, the process may proceed to step S22.

The control unit 43 repeats step S20 until it is determined that the predetermined number of wafers W have been processed. If it is determined that the predetermined number of wafers W have been processed, the control unit 43 measures temperature rising rate of the focus ring 30 (step S22). The temperature rising rate can be obtained based on temperature measured by the radiation thermometer 51, after heating the focus ring 30 while supplying constant electric power to the heater 52.

Next, the control unit 43 refers to the table storing information indicating the relationship between temperature rising rate and DC voltage that has been calculated in the pre-process of the DC voltage control process, to specify an optimal DC voltage value corresponding to the temperature rising rate measured at step S22 (step S24). For example, as illustrated in the graph (b) of FIG. 5, a DC voltage value corresponding to the measured temperature rising rate is uniquely specified.

Referring back to FIG. 6, the control unit 43 next controls output of the variable DC power source 28 so that the variable DC power source 28 applies DC voltage at the specified magnitude to the focus ring 30 (step S26), and the process terminates.

According to the DC voltage control process in the present embodiment, by calculating an optimal magnitude of DC voltage corresponding to temperature rising rate, an optimal magnitude of DC voltage corresponding to degree of abrasion of the focus ring 30 is estimated. Also, by applying DC voltage at the estimated optimal magnitude corresponding to the degree of abrasion of the focus ring 30, sheath above the focus ring 30 and sheath above a wafer W are made to be at the same height. Thus, at least one of an occurrence of tilting and variation of an etching rate can be suppressed. For example, in a case in which the calculated optimal DC voltage value is 100 V, by applying DC voltage of 100 V to the focus ring 30, even if the abraded focus ring 30 is used, similar etching characteristics to that in a state in which the focus ring 30 is new (such as a vertical etching profile and uniform distribution of an etching rate) can be obtained.

As described above, even if the focus ring 30 has abraded, because similar etching characteristics to that in the state in which the focus ring 30 is new can be obtained by applying DC voltage to the focus ring 30, a replacement cycle of the focus ring 30 can be extended. A time required for replacing a focus ring 30 includes a time for opening the processing vessel 10, a time for replacing the focus ring 30 with a new one, a time for closing the processing vessel 10 after replacing the focus ring 30, a time for cleaning inside the processing vessel 10, and a time for making a condition inside the processing vessel 10 adequate by performing seasoning. Thus, by extending a replacement cycle of the focus ring 30, productivity is increased.

### MODIFIED EXAMPLE

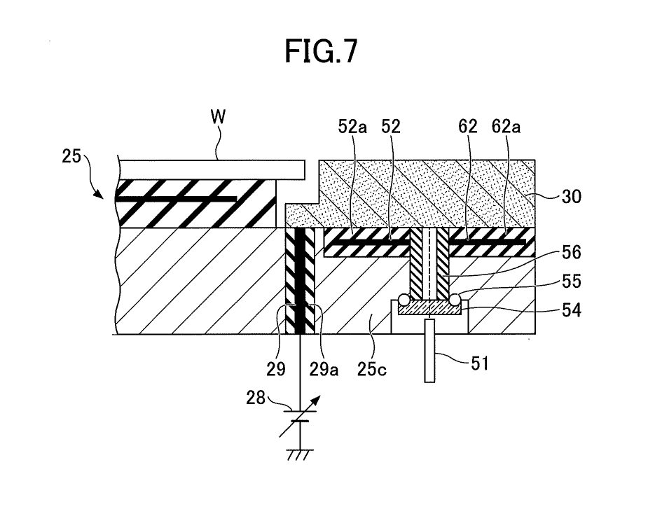

Next, a modified example of a peripheral structure of the focus ring 30 concerning temperature measurement of the focus ring 30 will be described with reference to FIG. 7. FIG. 7 is a diagram illustrating an example of a cross section of the peripheral structure of the focus ring according to the modified example.

In the example illustrated in FIG. 3, the radiation thermometer 51 is disposed so as to measure temperature at an outer circumferential side of the bottom surface of the focus ring 30. However, in the modified example illustrated in FIG. 7, the radiation thermometer 51 is disposed so as to measure temperature at a middle point between an outer circumference and an inner circumference of the bottom surface of the focus ring 30. Therefore, in the modified example illustrated in FIG. 7, the heater 52 coated with the insulator 52a and a heater 62 coated with an insulator 62a are respectively provided at locations on the base 25c corresponding to the inner circumference and the outer circumference of the bottom surface of the focus ring 30.

According to the above described structure, a position, in which temperature is measured by the radiation thermometer 51 according to the modified example, is closer to the heater 52 or 62 as compared with a position in which temperature is measured by the radiation thermometer 51 according to the first-described embodiment, and the radiation thermometer 51 according to the modified example tends to measure temperature at a middle point between an outer circumference and an inner circumference of the bottom surface of the focus ring 30. However, a positional relationship between the heater 52 or 62 and the radiation thermometer 51 is not limited to a specific one. The radiation thermometer 51 may be close to the heater 52 or 62 or be apart from the heater 52 or 62. Also, a position of the radiation thermometer 51 is not limited to the outer circumferential side of the bottom surface of the focus ring 30 or the middle point between the outer circumference and the inner circumference of the focus ring 30. For example, the radiation thermometer 51 may be disposed so as to measure temperature at the inner circumferential side of the bottom surface of the focus ring 30. In any case, by performing the pre-process of the DC voltage control process for obtaining the information indicating a relationship between temperature rising rate of the focus ring 30 and DC voltage, DC voltage at an optimal magnitude can be applied to the focus ring 30.

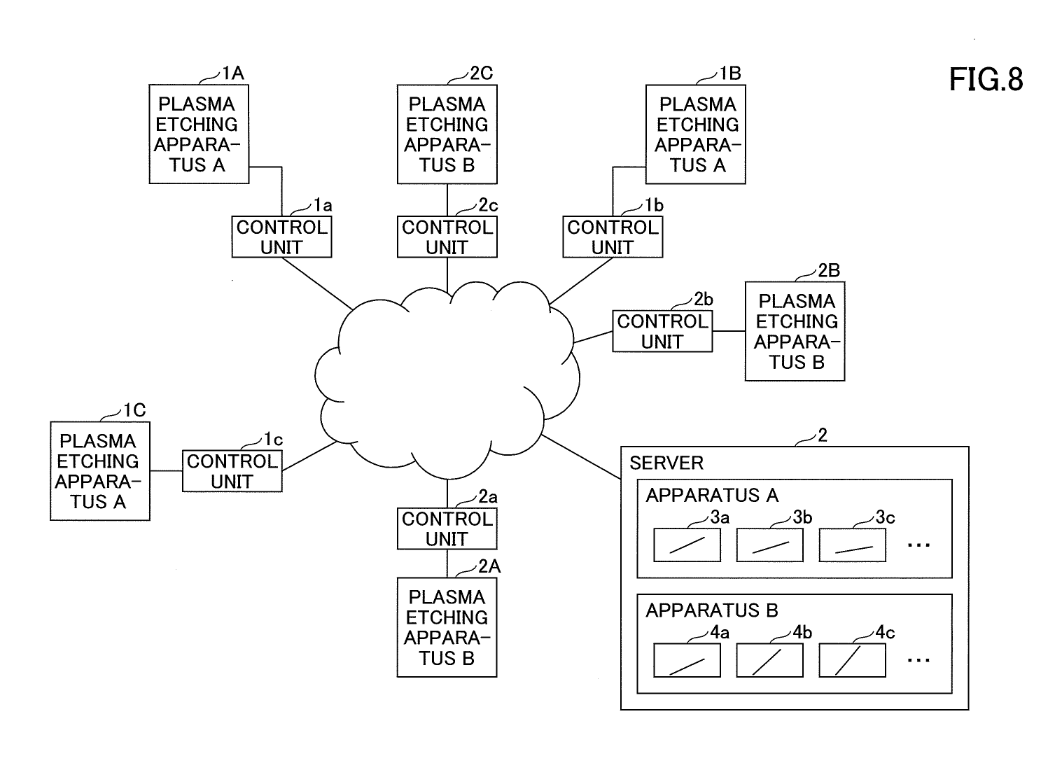

Lastly, an example of a system utilizing the information stored in the memory 43b by the control unit 43 which indicates the relationship between temperature rising rate and DC voltage, and an example of control performed by a server 2 in the system, will be described with reference to FIG. 8. FIG. 8 is a diagram illustrating an example of a system for controlling DC voltage applied to the focus ring of the plasma etching apparatus according to the above-described embodiment.

The system to be described below includes two types of plasma etching apparatuses, which are a plasma etching apparatus A (hereinafter simply referred to as an “apparatus A”), and a plasma etching apparatus B (hereinafter simply referred to as an “apparatus B”). The system also includes control units 1a, 1b, and 1c each of which controls a corresponding apparatus A, and includes control units 2a, 2b, and 2c each of which controls a corresponding apparatus B. The control units 1a to 1c and the control units 2a to 2c are connected to the server 2 via a network.

Examples of the apparatus A are, but are not limited to, a plasma etching apparatus 1A, a plasma etching apparatus 1B, and a plasma etching apparatus 1C. The plasma etching apparatuses 1A, 1B, and 1C are controlled by the control units 1a, 1b, and 1c respectively.

Examples of the apparatus B are, but are not limited to, a plasma etching apparatus 2A, a plasma etching apparatus 2B, and a plasma etching apparatus 2C. The plasma etching apparatuses 2A, 2B, and 2C are controlled by the control units 2a, 2b, and 2c respectively.

Each of the control units 1a, 1b, 1c, 2a, 2b, and 2c transmits, to the server 2, information indicating the relationship between temperature rising rate and DC voltage which is stored in its memory. The server 2 receives the information (3a, 3b, and 3c) indicating the relationship between temperature rising rate and DC voltage respectively from the control units 1a, 1b, and 1c controlling the apparatus A. The server 2 also receives the information (4a, 4b, and 4c) indicating the relationship between temperature rising rate and DC voltage respectively from the control units 2a, 2b, and 2c controlling the apparatus B. In FIG. 8, the information indicating the relationship between temperature rising rate and DC voltage is represented as a symbol of a graph, for convenience.

The server 2 classifies the received information into a category with respect to the apparatus A and a category with respect to the apparatus B. The information 3a, 3b, and 3c indicating the relationship with respect to the apparatus A belongs to the category with respect to the apparatus A, and the information 4a, 4b, and 4c indicating the relationship with respect to the apparatus B belongs to the category with respect to the apparatus B.

The server 2 calculates an optimal value of DC voltage corresponding to temperature rising rate of the apparatus A, based on the information 3a, 3b, and 3c classified to the category with respect to the apparatus A. For example, when obtaining one optimal value of DC voltage corresponding to a certain temperature rising rate of the apparatus A, the server 2 may obtain the optimal value by calculating an average of each DC voltage value corresponding to the certain temperature rising rate of the apparatus A, based on the information 3a, 3b, and 3c. The server 2 may also obtain the optimal value by calculating a median of each DC voltage value corresponding to the certain temperature rising rate of the apparatus A. Alternatively, the server 2 may obtain the optimal value by calculating a maximum or a minimum of each DC voltage value corresponding to the certain temperature rising rate of the apparatus A. In another embodiment, the server 2 may obtain the optimal value by calculating a specific value among each DC voltage value corresponding to the certain temperature rising rate of the apparatus A, based on the information 3a, 3b, and 3c.

Similarly, the server 2 calculates an optimal value of DC voltage corresponding to temperature rising rate of the apparatus B, based on the information 4a, 4b, and 4c classified to the category with respect to the apparatus B. For example, when obtaining one optimal value of DC voltage corresponding to a certain temperature rising rate of the apparatus B, the server 2 may obtain the optimal value by calculating an average, a median, a maximum, or a minimum of each DC voltage value corresponding to the certain temperature rising rate of the apparatus B, based on the information 4a, 4b, and 4c. Alternatively, the server 2 may obtain the optimal value by calculating a specific value among each DC voltage value corresponding to the certain temperature rising rate of the apparatus B, based on the information 4a, 4b, and 4c.

The server 2 calculates an optimal value of DC voltage corresponding to temperature rising rate, from DC voltage corresponding to temperature rising rate of each plasma etching apparatus, and feeds the calculated optimal value of DC voltage corresponding to the temperature rising rate, back to the control units 1a, 1b, 1c, 2a, 2b, and 2c. Accordingly, the control units 1a to 2c can control DC voltage applied to the focus ring 30 by using the optimal value of DC voltage corresponding to degree of abrasion of the focus ring 30, which is obtained by using information of not only its own plasma etching apparatus but also other plasma etching apparatuses.

According to the above description, information about DC voltage corresponding to temperature rising rate measured in multiple plasma etching apparatuses belonging to the same category can be collected by the server 2. Thus, based on the information about DC voltage corresponding to temperature rising rate collected from the multiple plasma etching apparatuses, an optimal value of DC voltage corresponding to temperature rising rate can be calculated without variation. Accordingly, DC voltage of an optimal magnitude corresponding to degree of abrasion of the focus ring 30 can be applied to the focus ring 30 more precisely. Note that the server 2 may be implemented by a cloud computing environment.

As described above, according to the above-described embodiment, by applying, to the focus ring 30, appropriate DC voltage corresponding to degree of abrasion of the focus ring 30, at least one of occurrence of tilting and variation of an etching rate can be suppressed. Therefore, because a cycle of replacement of the focus ring 30, which is caused by abrasion of the focus ring 30, can be extended, productivity in the plasma etching apparatus is increased.

In the above embodiments, the plasma etching apparatus and the plasma etching method have been described. However, a plasma etching apparatus and a plasma etching method according to the present invention are not limited to the above embodiments. Various changes or enhancements can be made hereto within the scope of the present invention. Matters described in the above embodiments may be combined unless inconsistency occurs.

The plasma etching apparatus according to the present invention can be applicable to any type of plasma processing apparatuses, such as a capacitively coupled plasma (CCP) type, an inductively coupled plasma (ICP) type, a radial line slot antenna type, an electron cyclotron resonance plasma (ECR) type, and a helicon wave plasma (HWP) type.

In this specification, the semiconductor wafer W is referred to as an example of a workpiece. However, the workpiece is not limited to the semiconductor wafer. Examples of the workpiece may include various types of substrates used in an LCD (Liquid Crystal Display) or a FPD (Flat Panel Display), a CD substrate, or a printed circuit board.

What is claimed is:

1. A plasma etching apparatus comprising:
a processing vessel capable of being evacuated;
a lower electrode provided in the processing vessel, the lower electrode being configured to place a substrate;
an upper electrode provided in the processing vessel, the upper electrode being arranged in parallel with the lower electrode so as to face each other;
a process gas supply unit configured to supply process gas to a processing space between the upper electrode and the lower electrode;
a high frequency power supply unit configured to supply high frequency electric power for generating plasma from process gas;
a focus ring surrounding a periphery of the substrate;
a direct current (DC) power source configured to output DC voltage applied to the focus ring;
a heating unit configured to heat the focus ring; and
a temperature measurement unit configured to measure temperature of the focus ring.

2. The plasma etching apparatus according to claim 1, further comprising a control unit configured to control the DC voltage output by the DC power source, the control unit including a memory unit configured to store information indicating a relationship between temperature rising rate of the focus ring and DC voltage, wherein
the control unit is configured to control the DC voltage by referring to the information stored in the memory unit, based on the temperature of the focus ring measured by the temperature measurement unit.

3. The plasma etching apparatus according to claim 1, wherein the temperature measurement unit is configured to measure temperature of a bottom surface of the focus ring, as the temperature of the focus ring.

4. A plasma etching method comprising an etching step of etching a substrate by using the plasma etching apparatus according to claim 1,
wherein the etching step includes controlling the DC voltage applied to the focus ring by accessing a memory unit in the plasma etching apparatus to refer to information indicating a relationship between temperature rising rate of the focus ring and DC voltage, based on temperature of the focus ring measured by the temperature measurement unit.

5. The method according to claim 4, further comprising
a calculating step of calculating temperature rising rate of the focus ring, by measuring the temperature of the focus ring using the temperature measurement unit while raising temperature of the heating unit; and
a recording step of recording in the memory unit, as the information indicating the relationship between temperature rising rate of the focus ring and DC voltage, a relationship between the calculated temperature rising rate of the focus ring and an optimal value of DC voltage corresponding to the temperature rising rate of the focus ring, the recording step being performed before the etching step.

6. The method according to claim 4, the etching step further including calculating the temperature rising rate of the focus ring, by measuring the temperature of the focus ring using the temperature measurement unit while raising temperature of the heating unit;
wherein the controlling of the DC voltage is performed based on the calculated temperature rising rate.
